(19) United States
(12) Patent Application Publication
(10) Pub. No.: US 2025/0068050 A1
(43) Pub. Date: Feb. 27, 2025

(54) PHOTOMASK ASSEMBLY AND SEMICONDUCTOR CHIP MANUFACTURED USING THE SAME

(71) Applicant: SAMSUNG ELECTRONICS CO., LTD., Suwon-si (KR)

(72) Inventors: Munja Kim, Suwon-si (KR); Jongju Park, Suwon-si (KR); Byunghoon Lee, Suwon-si (KR); Yunhan Lee, Suwon-si (KR)

(21) Appl. No.: 18/678,622

(22) Filed: May 30, 2024

(30) Foreign Application Priority Data
Aug. 22, 2023 (KR) 10-2023-0110035
Nov. 7, 2023 (KR) 10-2023-0153095

(51) Int. Cl. G03F 1/24

(52) U.S. Cl. CPC G03F 1/24

(57) ABSTRACT

A photomask assembly includes a mask pattern providing an upper surface and including a plurality of pins extending in a vertical direction with respect to the upper surface, a pellicle membrane disposed to be spaced apart from the mask pattern in the vertical direction, and a frame assembly configured to support the pellicle membrane, wherein the frame assembly includes a frame body having a plurality of pin holes configured to respectively fasten the plurality of pins, a first magnetic member configured to surround the plurality of pin holes inside the frame body and generate an attractive force on the plurality of pins, and a second magnetic member disposed in a lower portion of the frame body and configured to generate an attractive force on the upper surface of the mask pattern.

### CROSS-REFERENCE TO RELATED APPLICATION

This application claims priority under 35 U.S.C. § 119 to Korean Patent Application No. 10-2023-0110035, filed on Aug. 22, 2023 and Korean Patent Application No. 10-2023-0153095, filed on Nov. 7, 2023, in the Korean Intellectual Property Office, the disclosure of which is incorporated by reference herein in their entirety.

### BACKGROUND

The present disclosure relates to a photomask assembly and a semiconductor chip manufactured using the same, and more specifically, to a photomask assembly including pellicles for extreme ultraviolet (EUV) exposure and a semiconductor chip manufactured using the same.

Pellicles are disposed on a photomask substrate at certain intervals to protect a surface of the photomask substrate from external particles and are maintained without deformation or damage for a certain period of time in an exposure environment for lithography.

### SUMMARY

Pellicles tend to be coupled to a photomask, so there is demand for a photomask assembly that may be bonded more efficiently while preventing external particles from penetrating the photomask. The present disclosure provides a photomask assembly in which a photomask and pellicles may be coupled to each other more efficiently and accurately, and a semiconductor chip manufactured using the same.

According to an aspect of the present disclosure, a photomask assembly includes: a mask pattern providing an upper surface and including a plurality of pins extending in a vertical direction with respect to the upper surface, a pellicle membrane disposed to be spaced apart from the mask pattern in the vertical direction, and a frame assembly configured to support the pellicle membrane, wherein the frame assembly includes a frame body having a plurality of pin holes configured to respectively fasten the plurality of pins, a first magnetic member configured to surround the plurality of pin holes inside the frame body and generate an attractive force on the plurality of pins, and a second magnetic member disposed in a lower portion of the frame body and configured to generate an attractive force on the upper surface of the mask pattern

According to another aspect of the present disclosure, a photomask assembly includes: a mask pattern providing an upper surface and comprising a plurality of pins extending in a vertical direction with respect to the upper surface, a pellicle membrane disposed to be spaced apart from the mask pattern in the vertical direction, a frame assembly configured to support the pellicle membrane, and an adhesive layer disposed between the pellicle membrane and the frame assembly and configured to attach the pellicle membrane to the frame assembly, wherein the frame assembly includes a frame body including a plurality of pin holes configured to respectively fasten the plurality of pins, a first magnetic member configured to surround the plurality of pin holes inside the frame body and generate an attractive force on the plurality of pins, a plurality of second magnetic members disposed to be spaced apart from each other in a lower portion of the frame body and each configured to generate an attractive force on the upper surface of the mask pattern, and a plurality of third magnetic members each disposed between a pair of second magnetic members among the plurality of second magnetic members spaced apart from each other in the lower portion of the frame body and each configured to generate an attractive force on the upper surface of the mask pattern.

According to another aspect of the present disclosure, a semiconductor chip is manufactured using a photomask assembly. The photomask assembly includes: a mask pattern providing an upper surface and including a plurality of pins each having a cylindrical shape extending in a vertical direction with respect to the upper surface, and a pellicle coupled to the mask pattern, the pellicle includes a pellicle membrane disposed to be spaced apart from the mask pattern in the vertical direction, a frame assembly having a square ring shape configured to support the pellicle membrane, and an adhesive layer disposed between the pellicle membrane and the frame assembly and configured to attach the pellicle membrane to the frame assembly, and the frame assembly includes a frame body having four cylindrical pin holes configured to respectively fasten the plurality of pins, a first magnetic member configured to surround the four pin holes inside the frame body and generate an attractive force on the plurality of pins, and a plurality of second magnetic members spaced apart from each other in a lower portion of the frame body and each configured to generate an attractive force on the upper surface of the mask pattern.

### BRIEF DESCRIPTION OF THE DRAWINGS

FIG. 1 is a plan view of an example of a photomask assembly.

FIG. 2 is an enlarged view of area P in FIG. 1.

FIG. 3 is a cross-sectional view taken along line A-A′ of FIG. 1.

FIG. 4 is a cross-sectional view taken along line B-B′ of FIG. 1.

FIG. 5 is an enlarged view corresponding to FIG. 2 and showing an example of a photomask assembly.

FIG. 6 is a plan view of an example of a photomask assembly.

FIG. 7 is a plan view of an example of a photomask assembly.

FIG. 8 is a cross-sectional view taken along line C-C′ of FIG. 7.

FIG. 9 is a cross-sectional view taken along line D-D′ of FIG. 7.

FIG. 10 is a plan view of an example of a photomask assembly.

FIG. 11 is a cross-sectional view taken along line E-E′ of FIG. 10.

FIG. 12 is a cross-sectional view of an example of a photomask assembly.

FIG. 13 is a cross-sectional view illustrating a schematic configuration of an example of a semiconductor chip manufacturing apparatus.

FIG. 14 depicts a schematic of an example of a method of performing a reflective photolithography process by using a reticle to which a pellicle is attached.

### DETAILED DESCRIPTION

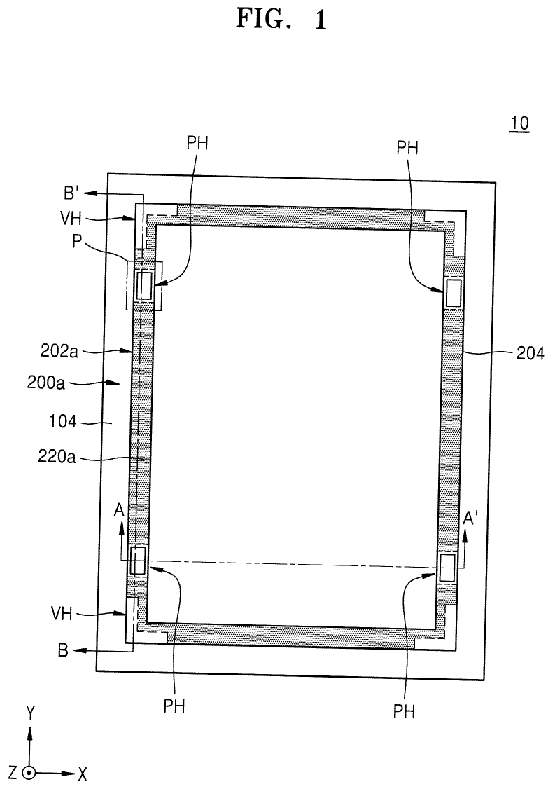

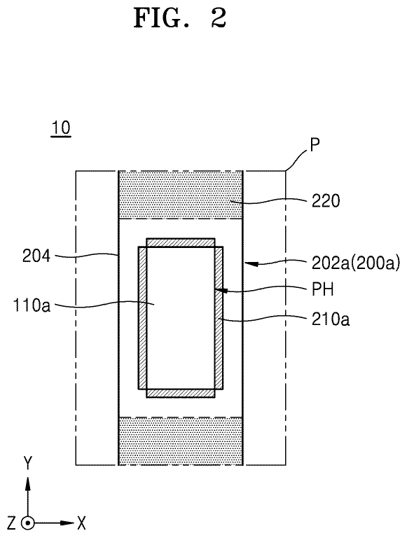

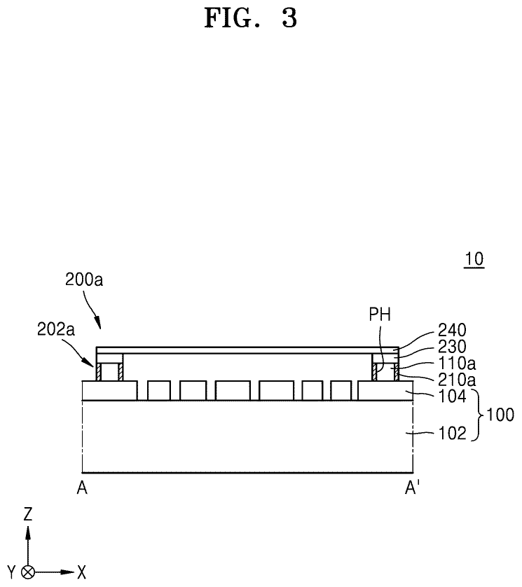

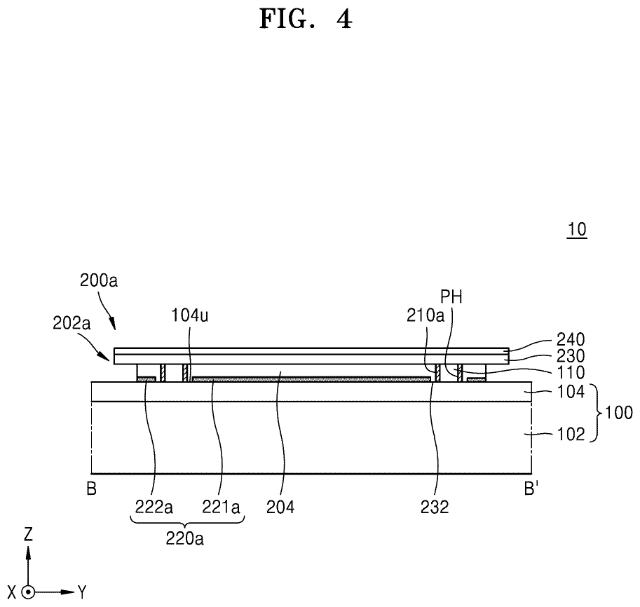

FIG. 1 is a plan view of an example of a photomask assembly 10. FIG. 2 is an enlarged view of area P in FIG. 1. FIG. 3 is a cross-sectional view taken along line A-A′ of FIG. 1. FIG. 4 is a cross-sectional view taken along line B-B′ of FIG. 1.

The photomask assembly 10 includes a mask structure 100. The mask structure 100 includes a mask substrate 102 providing an upper surface parallel to a lateral direction and a mask pattern 104 disposed on the mask substrate 102. In the present specification, a direction parallel to the upper surface of the mask substrate 102 and along a short corner of the mask substrate 102 in a square shape is referred to as a first horizontal direction (X direction). In addition, a direction parallel to the upper surface of the mask substrate 102, orthogonal to the first horizontal direction (X direction), and along a long corner of the mask substrate 102 is referred to as a second horizontal direction (Y direction). In addition, a direction orthogonal to the upper surface of the mask substrate 102 and at the same time orthogonal to the first horizontal direction (X direction) and the second horizontal direction (Y direction) is referred to as a vertical direction (Z direction). The above-mentioned lateral direction means the first horizontal direction (X direction) or the second horizontal direction (Y direction). In some implementations, the mask structure 100 may be an extreme ultraviolet (EUV) mask structure.

In some implementations, the mask substrate 102 may include relatively defect-free silicon oxide (e.g., SiO₂), borosilicate glass, soda-lime glass, calcium fluoride, a low thermal expansion material, an ultra-low expansion material, or a combination thereof. However, the material included in the mask substrate 102 is not limited to the materials listed above. The mask pattern 104 disposed on the mask substrate 102 may be designed according to a pattern of a pre-designed integrated circuit through a lithography patterning process. A material layer of the mask pattern 104 may be patterned to have an opening area through which a radiation beam may pass without being absorbed and an absorption area through which the radiation beam may be completely or partially blocked.

The mask pattern 104 may include pins 110 disposed on an upper surface 104u and extending in the vertical direction (Z direction). The mask pattern 104 may include a plurality of pins 110a, and the plurality of pins 110a may be disposed at the same distance from the center of the mask pattern 104. In FIG. 1, the plurality of pins 110a includes four pins 110a, but the number of the pins 110a is not limited thereto. As shown in FIG. 2, the pin 110a may have a square pillar shape with a square upper surface. A width of the pin 110a in a lateral direction may be smaller than a width of a frame body 204 in the lateral direction, which will be described below. Specifically, the width of the pin 110a in the first horizontal direction (X direction) is smaller than the width of the frame body 204 in the first horizontal direction (X direction).

In some implementations, the mask pattern 104 may include metal, metal alloy, metal silicide, metal nitride, metal oxide, metal oxynitride, or other applicable materials. For example, the mask pattern 104 may include Cr, MoxSiy, TaxSiy, Mo, NbxOy, Ti, Ta, CrxNy, MoxOy, MoxNy, CrxOy, TixNy, ZrxNy, TixOy, TaxNy, TaxOy, SixOy, NbxNy, SixNy, ZrxNy, AlxOyNz, TaxByOz, TaxByNz, AgxOy, AgxNy, Ni, NixOy, or NixOyNz.

As shown in FIGS. 3 and 4, the photomask assembly 10 may include a pellicle 200a. At this time, the pellicle 200a may be a pellicle for EUV light (EUVL) exposure. In some implementations, the pellicle 200a may be aligned on the mask pattern 104. The pellicle 200a may include a frame assembly 202a, a support layer 230, and a pellicle membrane 240.

In some implementations, the frame assembly 202a may include the frame body 204, first magnetic members 210a, and a second magnetic member 220a. In some implementations, the frame body 204 may have a square ring shape. When the pellicle 200a is mounted on the mask structure 100, a lower surface 232 of the frame body 204 may completely contact the upper surface 104u of the mask pattern 104.

The frame body 204 may include a plurality of pin holes PH configured to respectively fasten, e.g., surround, the plurality of pins 110a of the mask pattern 104. As shown in FIG. 2, each of the plurality of pin holes PH may have the square shape. When the pellicle 200a is coupled to the mask structure 100, the pin 110a of the mask pattern 104 is coupled to the pin hole PH of the frame body 204. At this time, in order to ensure that the pin 110a is completely fixed inside the pin hole PH, the size of the pin 110a and the size of the pin hole PH may be substantially equal in size, e.g., roughly the same provided finite tolerance (1% or less, 5% or less, etc).

In some implementations, the frame body 204 may include a ceramic material, a metallic material, a glass-ceramic material, or a combination thereof. The frame body 204 may be formed by a machining process, a forced forming process, a sintering process, a photochemical etching process. The method of forming the frame body 204, however, is not necessarily limited to the process methods listed above.

Vent holes VH may be formed in lower ends of edge portions of the frame body 204. The vent holes VH provide a passage through which gas inside the pellicle 200a may flow in and out when the pellicle 200a is coupled to the mask structure 100. When the photomask assembly 10 performs a process, air pressure of a space between the pellicle membrane 240 and the mask pattern 104 may increase due to gas generated between the pellicle membrane 240 of the pellicle 200a and the mask pattern 104. The pellicle membrane 240 may be damaged due to the increased air pressure. When the vent holes VH are formed in the frame body 204, gases generated during the process may leak to the outside through the vent holes VH. That is, the vent holes VH of the frame body 204 may prevent the pellicle membrane 240 from being damaged during the exposure process.

In some implementations, the vent holes VH may each have an ‘L’ shape, e.g., have two portions meeting at a right angle, being elbow shaped, or both. The vent holes VH may be respectively formed in the edge portions of the frame body 204 having the square ring shape with four edges. The vent holes VH may be formed to extend in the first horizontal direction (X direction) and the second horizontal direction (Y direction) with respect to the edge portions of the frame body 204. In addition, the vent holes VH do not overlap the plurality of pin holes PH in the vertical direction (Z direction). However, the vent holes VH are not necessarily limited to the above, and the number of vent holes VH or the shape of each of the vent holes VH may vary depending on an embodiment.

The first magnetic members 210a may be disposed to surround the pin holes PH within the frame body 204. As shown in FIG. 2, a plurality of first magnetic members 210a may be respectively disposed along four side surfaces of the pin hole PH. At this time, the first magnetic member 210a may be exposed to an inner side surface of the pin hole PH. When one side surface of the first magnetic member 210a is exposed through the pin hole PH, and when the pellicle 200a is coupled to the mask structure 100, the first magnetic member 210a may contact the side surfaces of the pin 110a. The pin 110a may also include a magnetic material, and the first magnetic member 210a may be configured to generate an attractive force on the pin 110a. When the pellicle 200a is coupled to the mask structure 100, the first magnetic member 210a may fix the pin 110a with a magnetic force such that the pin 110a is not removed from the pin hole PH. At this time, when the first magnetic member 210a fixes the pin 110a with the magnetic force while being spaced apart from the pin 110a and fastened to the pin hole PH without contacting the side surfaces of the pin 110a, a coupling force may be weak. However, in this example, when the first magnetic member 210a contacts the side surfaces of the pin 110a and fixes the pin 110a to the pin hole PH with the magnetic force, the first magnetic member 210a may be coupled to the pin 110a with a stronger coupling force. The first magnetic member 210a may include a magnet. For example, the first magnetic members 210a may include a neodymium magnet. However, the magnet included in the first magnetic member 210a is not necessarily limited to the above.

As shown in FIG. 2, the plurality of first magnetic members 210a may be respectively disposed along the four side surfaces of the pin hole PH. The plurality of first magnetic members 210a may respectively contact four side surfaces of the pin 110a fastened to the pin hole PH. However, the shape and arrangement of the first magnetic members 210a are not limited to those shown in FIG. 2, and the first magnetic member 210a may have a single square ring shape. However, even in this case, four side surfaces of the first magnetic members 210a may be exposed through the pin hole PH.

As shown in FIG. 4, the second magnetic member 220a may be disposed on the lower portion of the frame body 204 to generate an attractive force on the upper surface 104u of the mask pattern 104. As shown in FIG. 1, the second magnetic member 220a may be disposed within the frame body 204 with the same width as the lateral width of the frame body 204. At this time, a lower surface of the second magnetic member 220a may be exposed to the outside of the frame body 204. This means that the lower surface of the second magnetic member 220a and the lower surface 232 of the frame body 204 may be defined as being on the same plane. When the lower surface of the second magnetic member 220a is exposed, and when the pellicle 200a is coupled to the mask structure 100, the second magnetic member 220a may contact the upper surface 104u of the mask pattern 104. The mask pattern 104 may include a material that generates an attractive force with a magnetic member (e.g., the second magnetic member 220a). For example, the mask pattern 104 may include metal.

The second magnetic member 220a may be configured to generate an attractive force on the mask pattern 104. When the pellicle 200a is coupled to the mask structure 100, the second magnetic member 220a may apply an attractive force to the mask pattern 104 such that the frame body 204 is fixed to the mask pattern 104. When the second magnetic member 220a is fixed to the mask pattern 104 with a magnetic force while being spaced apart from the mask pattern 104 without contacting the upper surface 104u of the mask pattern 104, the coupling force may be weak. However, when the lower surface of the second magnetic member 220a contacts the upper surface 104u of the mask pattern 104, the second magnetic member 220a may be coupled to the mask pattern 104 with a stronger bonding force. The second magnetic member 220a may include a magnet. For example, the second magnetic member 220a may include a neodymium magnet. However, the magnet included in the second magnetic member 220a is not necessarily limited to the above.

In some implementations, the second magnetic member 220a may include a first portion 221a extending in the second horizontal direction (Y direction) and a second portion 222a extending in the first horizontal direction (X direction) along the edge portion. At this time, as shown in FIG. 1, the frame body 204 may have the square ring shape with short corners in the first horizontal direction (X direction) and long corners in the second horizontal direction (Y direction). The first portion 221a of the second magnetic member 220a may extend along the long corners of the frame body 204, and the second portion 222a may extend along the short corners of the frame body 204. At this time, the first portion 221a and the second portion 222a may be spaced apart from each other with the pin hole PH of the frame body 204 disposed therebetween. The first magnetic member 210a may be disposed in the pin hole PH of the frame body 204, and thus, the second magnetic member 220a may not overlap the pin hole PH and the first magnetic member 210a in the vertical direction (Z direction). Magnetic forces superimpose, so when the second magnetic member 220a overlaps the first magnetic member 210a along the vertical direction (Z direction), the attractive magnetic forces of the second magnetic member 220a and the magnetic force of the first magnetic member 210a may partially cancel each other out for an object located between the first and second magnetic members 210a and 220a. Accordingly, the first magnetic member 210a may be spaced apart from the second magnetic member 220a in the first horizontal direction (X direction) or the second horizontal direction (Y direction) from a horizontal perspective, e.g., when viewed along the X or Y directions.

As shown in FIG. 4, the first magnetic member 210a may be disposed to surround the pin hole PH within the frame body 204, and thus, a vertical length of the first magnetic member 210a may be substantially the same as a vertical length of the frame body 204. The second magnetic member 220a is disposed on the lower end of the frame body 204, and thus, the length of the first magnetic member 210a in the vertical direction (Z direction) may be longer than the vertical direction (Z direction) of the second magnetic member 220a.

In some implementations, the pellicle membrane 240 may include a carbon-containing thin film and a reinforcement layer coated on a surface of the carbon-containing thin film. The reinforcement layer may include a boron (B)-containing material, a silicon (Si)-containing material, or a transition metal. The boron-containing material may include element boron, B4C, boron oxide, boron nitride, or a combination thereof. The silicon-containing material may include silicon oxide, silicon nitride, silicon oxynitride, or a combination thereof. The transition metal may be ruthenium (Ru), zirconium (Zr), molybdenum (Mo), or a combination thereof. In some implementations, the pellicle membrane 240 may have a thickness of about 5 nm to about 200 nm.

A process of attaching the pellicle membrane 240 onto the frame assembly 202a may be performed manually by an operator or through an automated process using machine. The support layer 230 may be used to attach the pellicle membrane 240 onto the frame assembly 202a. The thickness of the support layer 230 may be selected within a range of about 1 nm to about 10 nm. The support layer 230 may include a material suitable for supporting the pellicle membrane 240 disposed on the support layer 230, and may include, for example, glass, silicon, plastic, or metal.

In addition, an adhesive material may be used to attach the pellicle membrane 240 to the support layer 230. The adhesive material may be disposed between the pellicle membrane 240 and the support layer 230. The adhesive material may include a curable material or a non-curable material. As an example of the non-curable material, a dry film resist (DFR), etc. may be used, but is not necessarily limited thereto. In addition, examples of the curable material may include thermosetting resin, a hardener, and a reducer. The thermosetting resin may include Bisphenol A epoxy resin, Bisphenol F epoxy resin, Novolac epoxy resin, Aliphatic epoxy resin, or Glycidylamine epoxy resin. The hardener may harden the thermosetting resin at a specific temperature or higher. The hardener may include amine or polyimide. However, examples of the adhesive material are not necessarily limited to the materials listed above.

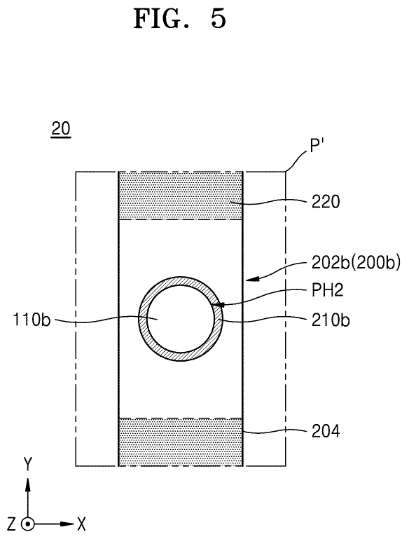

FIG. 5 is an enlarged view corresponding to FIG. 2 and showing an example of a photomask assembly 20. The photomask assembly 20 shown in FIG. 5 is similar to the photomask assembly 10 shown in FIGS. 1 and 2, except that shapes of a pin 110b and a pin hole PH2 are different. Accordingly, descriptions of components redundant with those of the photomask assembly 10 shown in FIGS. 1 and 2 will be omitted or simplified.

Referring to FIG. 5, the mask pattern 104 of the photomask assembly 20 includes the pin 110b in a cylindrical shape. In addition, the photomask assembly 20 may include a frame body 204 including the pin hole PH2 in a cylindrical shape.

A first magnetic member 210b may be disposed to surround the pin hole PH2 inside the frame body 204. As shown in FIG. 5, the first magnetic member 210b may have a ring shape and may be disposed along side surfaces of the pin hole PH2. At this time, the first magnetic member 210b may be exposed on an inner side surface of the pin hole PH2. When one surface of the first magnetic member 210b is exposed to the outside through the pin hole PH2, e.g., faces the pin hole PH2, and when a pellicle 200b is coupled to the mask structure 100, the first magnetic member 210b may contact side surfaces of the pin 110b. A material of the first magnetic member 210b and a material of the pin 110b may be substantially the same as a material of the first magnetic member 210a and a material of the pin 110a respectively shown in FIGS. 1 and 2.

The pin 110b may also include a magnetic material. The first magnetic member 210b may be configured to generate an attractive force on the pin 110b. When the pellicle 200b is coupled to the mask structure 100, the first magnetic member 210b may fix the pin 110b with a magnetic force such that the pin 110b is not removed from the pin hole PH2. When the first magnetic member 210b fixes the pin 110b with the magnetic force while being spaced apart from the pin 110b and fastened to the pin hole PH2 without contacting the side surface of the pin 110b, a coupling force may be weak. However, when the first magnetic member 210b contacts the side surfaces of the pin 110b and fixes the pin 110b to the pin hole PH2 with the magnetic force, the first magnetic member 210b may be coupled to the pin 110b with a stronger coupling force.

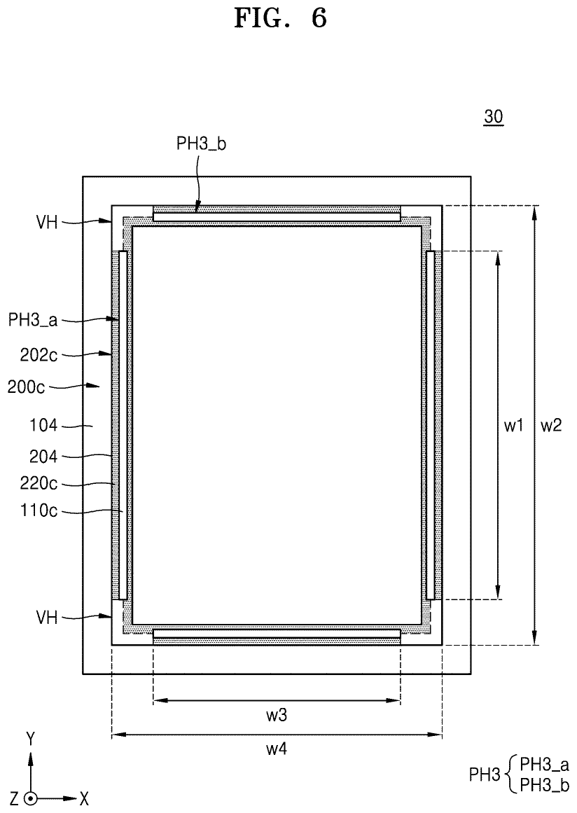

FIG. 6 is a plan view of an example of a photomask assembly 30. The photomask assembly 30 shown in FIG. 6 is similar to the photomask assembly 10 shown in FIGS. 1 and 2, except that a shape of a pin hole PH3 is different. Accordingly, descriptions of components redundant with those of the photomask assembly 10 shown in FIGS. 1 and 2 will be omitted or simplified.

The pin hole PH3 of the frame body 204 may have a square upper surface from a horizontal perspective. However, the pin hole PH3 shown in FIG. 6 may have an upper surface that is longer than the pin hole PH shown in FIG. 1 in a lateral direction. Specifically, a plurality of pin holes PH3 may each include a first pin hole PH3_a extending in the second horizontal direction (Y direction), and a second pin hole PH3_b extending in the first horizontal direction (X direction). The first pin hole PH3_a may have a first width w1 extending relatively long in the second horizontal direction (Y direction), and the second pin hole PH3_b may have a first width w1 extending relatively long in the first horizontal direction (X direction).

The frame body 204 may have a rectangular ring shape with corners in the second horizontal direction (Y direction) longer than corners in the first horizontal direction (X direction). The frame body 204 may have a second width w2 in the second horizontal direction (Y direction) and a fourth width w4 in the first horizontal direction (X direction). At this time, the second width w2 is larger than the fourth width w4. The first width w1 of the first pin hole PH3_a in the second horizontal direction (Y direction) may be longer than half the second width w2 of the frame body 204, and the third width w3 of the second pin hole PH3_b in the first horizontal direction (X direction) may be longer than half the fourth width w4 of the frame body 204. When the pin hole PH3 has a long width in the lateral direction in correspondence to the length of the frame body 204 in the lateral direction (e.g., the first horizontal direction (X direction) or the second horizontal direction (Y direction), a pin 110c may be stably fastened to the pin hole PH3. At this time, the pin 110c may have substantially the same dimension as the pin hole PH3 in correspondence to the size and shape of the pin hole PH3 when tolerance is not considered.

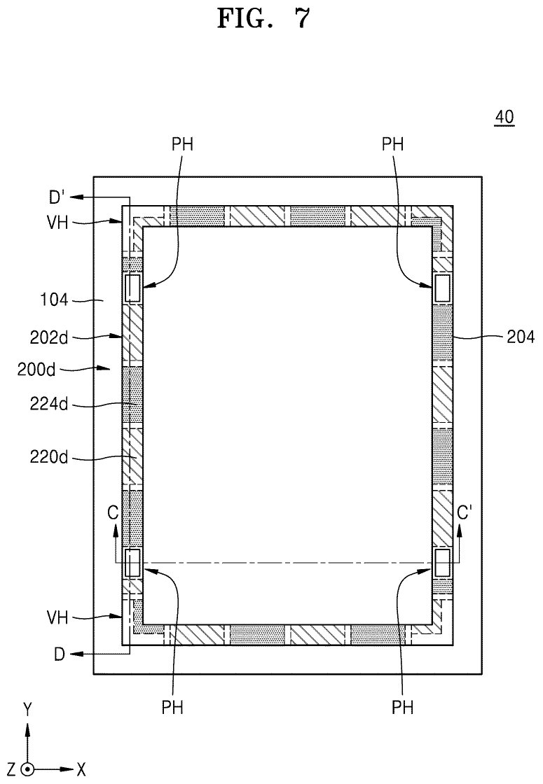

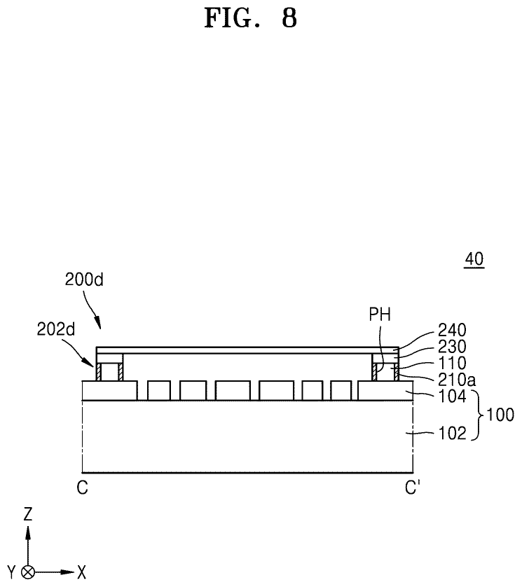

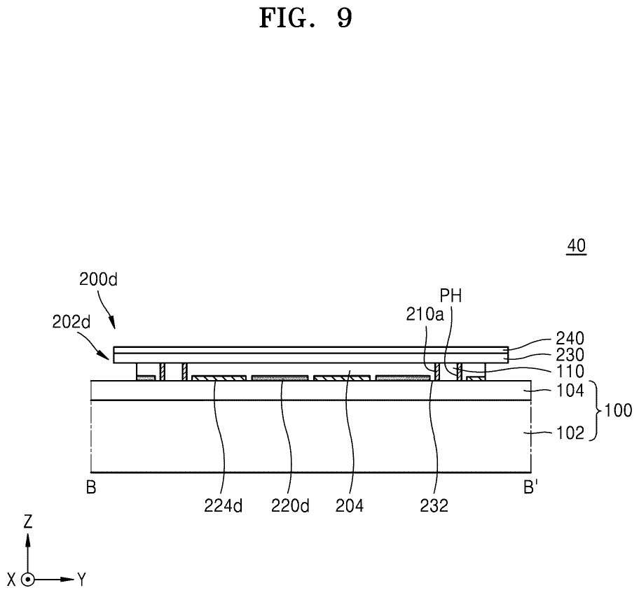

FIG. 7 is a plan view of an example of a photomask assembly 40. FIG. 8 is a cross-sectional view taken along line C-C′ of FIG. 7, and FIG. 9 is a cross-sectional view taken along line D-D′ of FIG. 7. The photomask assembly 40 shown in FIGS. 7 to 9 is similar to the photomask assembly 10 shown in FIGS. 1 to 4 except that a frame assembly 202d includes a plurality of second magnetic members 220d and a plurality of third magnetic members 224d alternately disposed on a lower end of the frame body 204. Therefore, descriptions of components that are the same as those of the photomask assembly 10 shown in FIGS. 1 to 4 will be omitted or simplified.

In some implementations, the frame assembly 202d may include the plurality of second magnetic members 220d disposed to be spaced apart from each other in a lower portion of the frame body 204 and configured to generate an attractive force on an upper surface of the mask pattern 104, and the plurality of third magnetic members 224d disposed between a pair of second magnetic members 220d among the plurality of second magnetic members 220d spaced apart from the lower portion of the frame body 204 and configured to form a magnetic force on an upper surface of the mask substrate 102. The third magnetic member 224d may include a magnet. For example, the third magnetic member 224d may include a neodymium magnet. However, the magnet included in the third magnetic member 224d is not necessarily limited to the above.

A thickness of each of the second magnetic member 220d and the third magnetic member 224d in the lateral direction (for example, the first horizontal direction (X direction) or the second horizontal direction (Y direction) is the same as a thickness of the frame body 204 in the lateral direction. In addition, the length of the second magnetic member 220d in a longitudinal direction may be the same as the length of the third magnetic member 224d in the longitudinal direction. That is, the plurality of second magnetic members 220d and the plurality of third magnetic members 224d may have the same specifications except for the configuration disposed on edge portions of the frame body 204.

Each of the plurality of second magnetic members 220d and each of the plurality of third magnetic members 224d may be disposed to be spaced apart from each other in the lateral direction. The second magnetic member 220d and the third magnetic member 224d disposed in one area of the frame body 204 extending in the first horizontal direction (X direction) may be spaced apart from each other in the first horizontal direction (X direction). In addition, the second magnetic member 220d and the third magnetic member 224d disposed in one area of the frame body 204 extending in the second horizontal direction (Y direction) may be spaced apart from each other in the second horizontal direction (Y direction). When the second magnetic member 220d and the third magnetic member 224d are spaced apart from each other in the lateral direction, a magnetic force of the second magnetic member 220d and a magnetic force of the third magnetic member 224d may not interfere with each other.

In some implementations, a magnetic material included in the second magnetic member 220d may be different from a magnetic material included in the third magnetic member 224d. Therefore, the magnetic permeability of the second magnetic member 220d and the magnetic permeability of the third magnetic member 224d may be different from each other, and the magnetic permeability of the second magnetic member 220d may be greater than the magnetic permeability of the third magnetic member 224d. When the magnetic permeability of the second magnetic member 220d is greater than the magnetic permeability of the third magnetic member 224d, an attractive force applied by the second magnetic member 220d to the upper surface of the mask pattern 104 may be higher than an attractive force applied by the third magnetic member 224d to the upper surface of the mask pattern 104.

The second magnetic member 220d and the third magnetic member 224d may be disposed on the lower portion of the frame body 204 to generate the attractive force on the upper surface of the mask substrate 102. As shown in FIG. 9, the second magnetic member 220d and the third magnetic member 224d may be disposed within the frame body 204 with the same width as the width of the frame body 204 in the lateral direction. At this time, a lower surface of the second magnetic member 220d and a lower surface of the third magnetic member 224d may be exposed to the outside of the frame body 204. When the lower surface of the second magnetic member 220d and the lower surface of the third magnetic member 224d are exposed to the outside, and when a pellicle 200d is coupled to the mask structure 100, the second magnetic member 220d and the third magnetic member 224d may contact the upper surface of the mask pattern 104. When the second magnetic member 220d and the third magnetic member 224d fix the mask pattern 104 with the magnetic force while being spaced apart from the mask pattern 104 without contacting the upper surface of the mask pattern 104, a coupling force may be weak. However, when the lower surface of the second magnetic member 220d and the lower surface of the third magnetic member 224d contact the upper surface of the mask pattern 104, the second magnetic member 220d and the third magnetic member 224d may be coupled to the mask pattern 104 with a stronger coupling force.

The first magnetic member 210a may be disposed in the pin hole PH of the frame body 204, and thus, the second magnetic member 220d and the third magnetic member 224d may not overlap the pin hole PH and the first magnetic member 210a in the vertical direction (Z direction). When the second magnetic member 220d or the third magnetic member 224d overlaps the first magnetic member 210a in the vertical direction (Z direction), a magnetic force of the second magnetic member 220d or a magnetic force of the third magnetic member 224d may interfere with a magnetic force of the first magnetic member 210a.

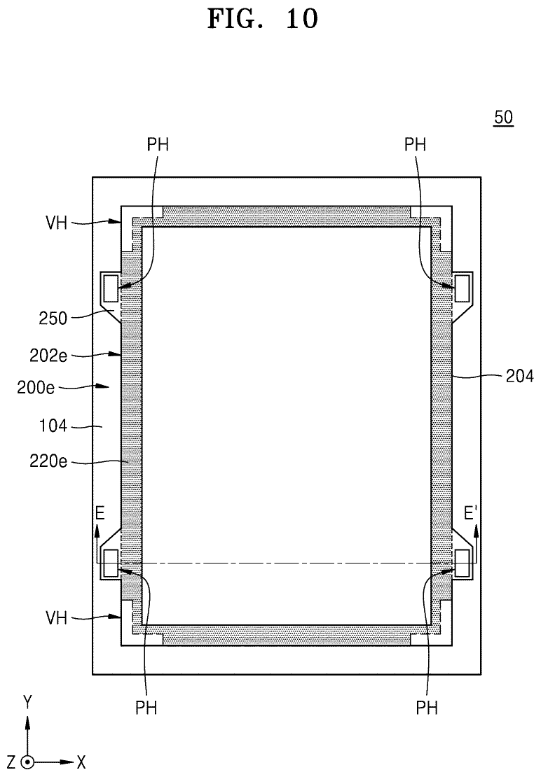

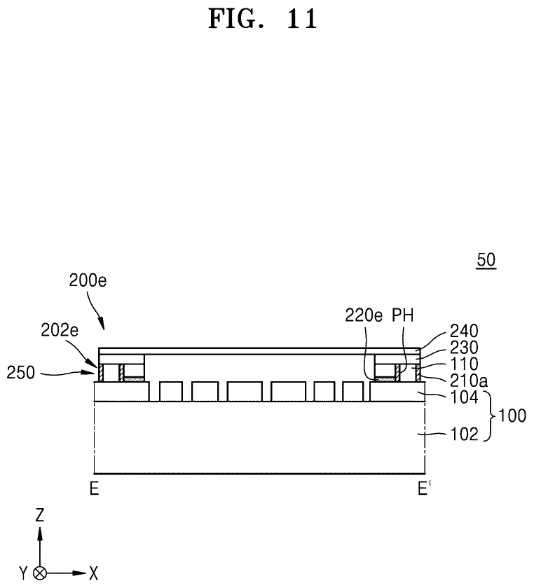

FIG. 10 is a plan view of an example of a photomask assembly 50. FIG. 11 is a cross-sectional view taken along line E-E′ of FIG. 10. The photomask assembly 50 shown in FIGS. 10 and 11 is similar to the photomask assembly 10 shown in FIGS. 1 and 2, except that the frame body 204 includes protrusions 250. Accordingly, descriptions of components redundant with those of the photomask assembly 10 shown in FIGS. 1 and 2 will be omitted or simplified.

Referring to FIGS. 10 and 11, the frame body 204 of the photomask assembly includes the protrusions 250. The protrusion 250 may be formed integrally with a frame having a square ring shape and protrude from a lateral direction. As shown in FIG. 10, the protrusions 250 may protrude from the frame having the square ring shape in the first horizontal direction (X direction) and may include a total of four protrusions. However, the number of protrusions 250 may vary. The pin hole PH may be formed in each of the plurality of protrusions 250. The pin hole PH may be configured to fasten the pin 110 of the mask pattern 104.

A frame assembly 202e shown in FIGS. 10 and 11 may include a second magnetic member 220e formed in a lower portion of the frame body 204. However, unlike the second magnetic member 220a shown in FIGS. 1 and 2, the second magnetic member 220e shown in FIGS. 10 and 11 may not be separated from the pin hole PH but may be integrally formed along a lower surface of the frame body 204. Therefore, as shown in FIG. 11, the first magnetic member 210a and the second magnetic member 220e may be disposed side by side in the first horizontal direction (X direction).

As mentioned above, the first magnetic member 210a and the second magnetic member 220c may not overlap each other in the vertical direction (Z direction) such that their magnetic forces do not interfere with each other. When the frame assembly 202e is coupled to the mask structure 100, because the first magnetic member 210a surrounding the pin hole PH does not overlap the frame body 204 having the square ring shape, the second magnetic member 220e may be disposed integrally along the lower surface of the frame body 204 having the square ring shape without being broken. Accordingly, the second magnetic member 220c shown in FIGS. 10 and 11 may be formed to have a larger area than the second magnetic member 220e shown in FIGS. 1 and 2. The second magnetic member 220e may have a larger area, and thus, the frame assembly 202c may be more effectively coupled to the mask structure 100.

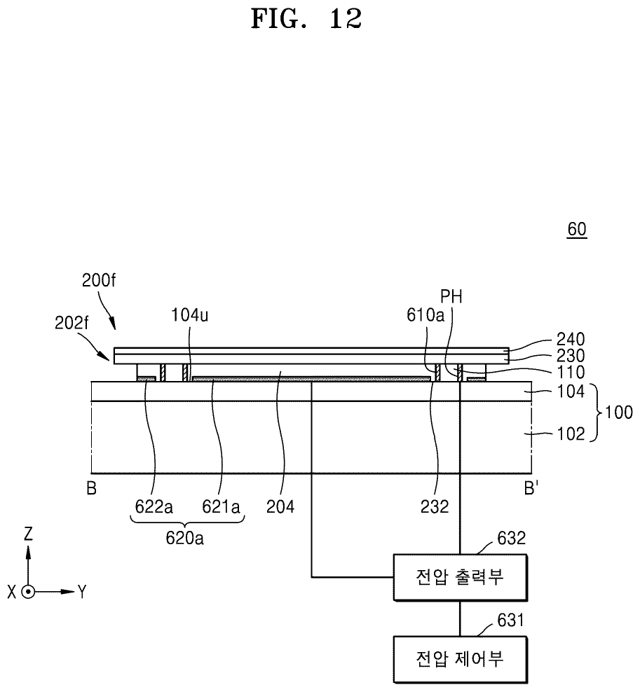

FIG. 12 is a cross-sectional view of another example of a photomask assembly 60. Specifically, FIG. 12 is a cross-sectional view corresponding to the cross-sectional view of FIG. 4. The photomask assembly 60 shown in FIG. 12 is similar to the photomask assembly 10 shown in FIG. 4, except that a first magnetic member 610a and a second magnetic member 620a are electromagnets, and the photomask assembly 60 further includes a voltage output unit 632 and a voltage control unit 631 electrically connected to the first magnetic member 610a and the second magnetic member 620a, respectively. Therefore, descriptions of components already mentioned with reference to FIGS. 1 to 4 will be simplified or omitted.

Referring to FIG. 12, the first magnetic member 610a and the second magnetic member 620a may be electromagnets whose magnetic forces vary depending on the applied electrical energy. The first magnetic member 610a and the second magnetic member 620a may be formed by winding a coil around a core. When current flows through the coil due to the applied driving voltage, the first magnetic member 610a and the second magnetic member 620a generate magnetism according to a change in the flowing current. As an example, the core may be implemented as a ferrite core or a permalloy core, e.g., ferromagnetic materials to reduce leakage magnetic flux and the fringing effect. The coil may be implemented as a material such as a conductive wire, e.g., a copper wire, to facilitate the flow of current.

In some implementations, the voltage output unit 632 changes a level of an input voltage input from an input power unit by the control of the voltage control unit 631 and applies the changed level of the input voltage to each of the first magnetic member 610a and the second magnetic member 620a as the driving voltage. The voltage output unit 632 changes the level of the input voltage based on a control signal input from the voltage control unit 631.

When the first magnetic member 610a is implemented as the electromagnet, no current may flow through the first magnetic member 610a before the pin 110 is fastened to the pin hole PH when a pellicle 200f is coupled onto the mask pattern 104. After the pin 110 is fastened to the pin hole PH, current flows through the first magnetic member 610a by the voltage output unit 632, and the first magnetic member 610a applies a magnetic force to the pin 110.

When the second magnetic member 620a is implemented as the electromagnet, no current may flow through the second magnetic member 620a before the frame body 204 contacts the mask pattern 104 when the pellicle 200f is coupled onto the mask pattern 104. After the frame body 204 contacts the mask pattern 104, current flows through the second magnetic member 620a by the voltage output unit 632, and the second magnetic member 620a applies a magnetic force to the mask pattern 104. The second magnetic member 620a may include a first portion 621a extending in the second horizontal direction (Y direction) and a second portion 622a extending in the first horizontal direction (X direction) along edge portions.

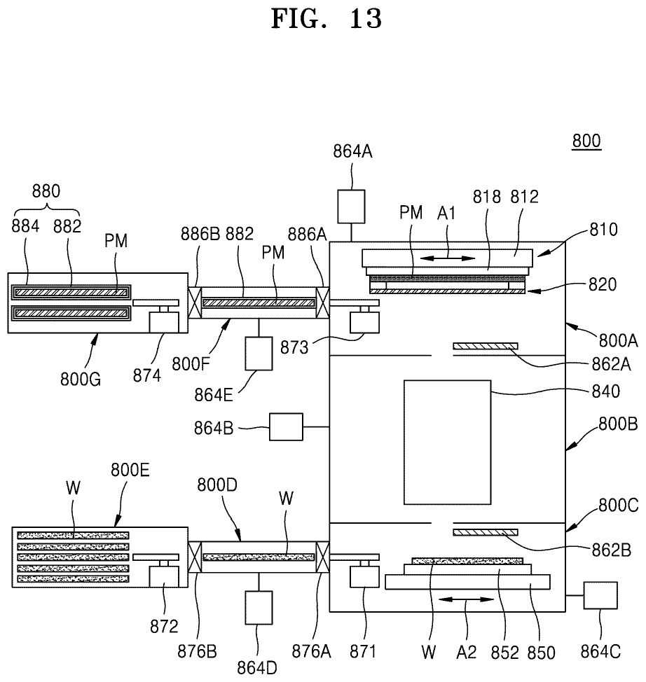

FIG. 13 is a cross-sectional view illustrating a schematic configuration of an example of a semiconductor chip manufacturing apparatus 800.

FIG. 13 shows the semiconductor chip manufacturing apparatus 800 configured as a photomask assembly that reduces and transfers an image of a pattern drawn on a photomask PM (or “reticle”) to a wafer W under vacuum in a projection optical system 840 using EUV light.

Referring to FIG. 13, the semiconductor chip manufacturing apparatus 800 includes a mask stage area 800A, a projection optical system area 800B, and a wafer stage area 800C.

The mask stage 810 in the mask stage area 800A includes a mask stage support 812 and a mask holder system 818 fixed to the mask stage support 812. The mask holder system 818 fixes the photomask PM. In some implementations, the mask holder system 818 may be configured as an electrostatic chuck and may, through adsorption, hold the photomask PM via an electrostatic force.

A pellicle 820 may be fixed on the photomask PM. In some implementations, the pellicle 820 may include the pellicle 200a, 200b, 200c, 200d, 200c, or 200f as described with reference to FIGS. 1 to 12, or a variant thereof.

The mask stage 810 may move the photomask PM, which is supported and fixed by the mask stage supporter 812, in a scan direction indicated by arrow A1.

The projection optical system 840 transferring a pattern formed on the photomask PM to the wafer W in the wafer stage area 800C may be located in the projection optical system area 800B. The wafer W may be fixed and held onto a wafer chuck 852 of a wafer stage 850. The wafer chuck 852 may move the wafer W in a scan direction indicated by arrow A2. The wafer W may include semiconductor chips manufactured using the semiconductor chip manufacturing apparatus 800.

The mask stage area 800A including the mask stage 810, the projection optical system area 800B including the projection optical system 840, and the wafer stage area 800C including the wafer stage 850 may be separated by gate valves 862A and 862B. Vacuum exhaust apparatuses 864A, 864B, and 864C may be respectively connected to the mask stage area 800A, the projection optical system area 800B, and the wafer stage area 800C, and thus, pressure may be controlled independently.

A transfer hand 871 is installed to load or unload the wafer W between the wafer stage area 800C and a load lock chamber 800D. A vacuum exhaust apparatus 864D is connected to the load lock chamber 800D. The wafer W may be temporarily stored in a wafer load port 800E under an atmospheric pressure. A transfer hand 872 is installed to load or unload the wafer W between the load lock chamber 800D and the wafer load port 800E. A gate valve 876A is disposed between the wafer stage area 800C and the load lock chamber 800D. A gate valve 876B is disposed between the load lock chamber 800D and the wafer load port 800E.

A transfer hand 873 is installed to load or unload the photomask PM between the mask stage 810 of the mask stage area 800A and the mask load lock chamber 800F. A vacuum exhaust device 864E is connected to the mask load lock chamber 800F. The photomask PM may be temporarily stored under atmospheric pressure at the mask load port 800G. A transfer hand 874 is installed to load or unload the photomask PM between a mask load lock chamber 800F and a mask load port 800G. A gate valve 886A is inserted between the mask stage area 800A and the mask load lock chamber 800F. A gate valve 886B is inserted between the mask load lock chamber 800F and the mask load port 800G.

The photomask PM may be stored and transported while being accommodated in a photomask carrier 880 until being transported to the semiconductor chip manufacturing apparatus 800 from the outside, and may be transported to the mask load port 800G while being accommodated in the photomask carrier 880. Accordingly, the photomask PM may be effectively protected from an unnecessary contact with an external environment and external particle contamination.

The photomask carrier 880 may include an inner pod 882 and an outer pod 884 that provides a space to accommodate the inner pod 882. The inner pod 882 and the outer pod 884 may each include a standard mechanical interface (SMIF) pod that complies with the standard (SEMI standard E152-0709). The outer pod 884 may be referred to as a “reticle SMWHEN pod” that serves to protect the photomask PM when the photomask PM is transported between different manufacturing stations or between different locations. The inner pod 882 may serve to protect the photomask PM while the photomask PM is transported to a vacuum atmosphere or to the mask stage 810 and its vicinity. Depressurizing the surrounding environment from an atmospheric state to a vacuum state or the state of environment from changing from the vacuum state to the atmospheric state can create vortices of contaminant particles. As a result of the vortices of contaminant particles, contaminant particles floating around the photomask PM can contaminate the photomask PM. The inner pod 882 may serve to protect the photomask PM from the above environment until the photomask PM is transported to the vacuum atmosphere or to the mask stage 810 and its vicinity.

In an exposure process of a semiconductor apparatus manufacturing process, a latent image pattern is formed on a resist film by projecting and exposing a pattern formed on a photomask (reticle) onto a wafer on which the resist film is formed, and a resist pattern is formed on the wafer through a development process. However, when foreign substances, such as particles, exist on the photomask, the foreign substances may be transferred onto the wafer along with the pattern, causing pattern defects.

In a manufacturing process of a semiconductor apparatus formed with an extremely fine pattern, such as large scale integration (LSI) or very LSI (VLSI), a reduction projection exposure apparatus is used to form the latent image pattern on the resist film by reducing and projecting the pattern formed on the photomask onto the resist film formed on the wafer. As the mounting density of the semiconductor apparatus increases, the circuit pattern becomes more refined. Accordingly, the demand for refining an exposure line width in an exposure apparatus is increasing. Accordingly, in order to improve the resolution performance of the exposure apparatus, a method of reducing the wavelength of the exposure wavelength has been developed. So far, i-line (365 nm), KrF excimer laser (248 nm), ArF excimer laser (193 nm), and fluorine (F2) excimer laser (157 nm) exposure technologies have been developed, and recently, an exposure apparatus using EUV light or electron beam with wavelengths in the soft X-ray area around 6.75 nm to 13.5 nm has been developed. EUV light is strongly absorbed by air, e.g., air at atmospheric pressure, so the optical path being in a vacuum increases the likelihood of successfully transmitting the EUV radiation. Therefore, placing an optical system, a mask stage, and a wafer stage in a vacuum room with a higher airtightness than a F2 exposure device can be beneficial, as well as installing a load lock chamber at an transfer entrance of each of the wafer and a photomask to take in and out of the wafer or the photomask while maintaining a degree of vacuum.

In EUV exposure, a reflective photomask including multiple reflective films on a front layer surface where a pattern area is formed may be used as the photomask.

When the wavelength of exposure light is shortened to an EUV area, because there is a limit in selecting a transparent material in the EUV so far, the exposure process is performed without using a pellicle, or a pellicle including a pellicle thin film that relatively severely deteriorates due to heat during exposure and has a low tensile strength was used. To increase the transmittance to EUV, using a very thin pellicle film having a thickness less than several tens of nm can be effective. However, in order to alleviate deterioration due to heat during exposure, a carbon-based material with a relatively high emissivity may be used as the pellicle film. However, there is a problem that the carbon-based material is easily damaged by hydrogen plasma generated in a EUVL exposure environment.

The semiconductor chip manufacturing apparatus 800 protects the photomask PM by using the pellicle 820 even in the exposure process using a EUV light source. The pellicle 820 uses the carbon-based material as a main layer and adds a chemical reinforcement layer thereon to protect the carbon-based main layer, thereby securing a sufficient lifespan of the pellicle film despite hydrogen plasma generated in the EUVL exposure environment. In particular, because an intermixing layer exists between the carbon-based main layer and the chemical reinforcement layer, the adhesion between the carbon-based main layer and the chemical reinforcement layer may be greatly improved. Accordingly, not only the lifespan of the pellicle may be significantly increased, but also errors due to deterioration of the pellicle film during the exposure process may be effectively prevented, and a pattern having a desired shape may be effectively transferred to an accurate location on the wafer W to be exposed.

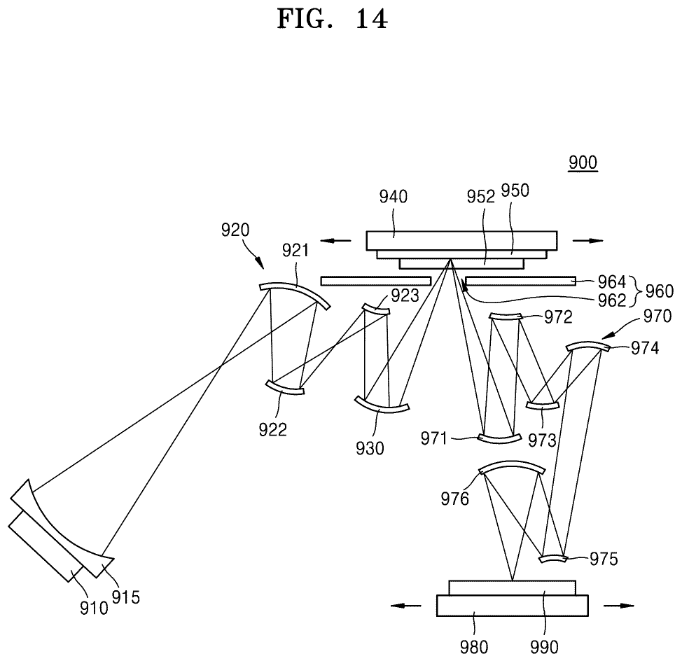

FIG. 14 depicts a schematic for performing an example of a reflective photolithography process by using a reticle 950 to which a pellicle 952 is attached.

Referring to FIG. 14, the method of performing the reflective photolithography process by using the reticle 950 to which the pellicle 952 is attached includes mounting the reticle 950 to which the pellicle 952 is attached. The pellicle 952 faces downward on a reticle stage 940 of a reflective photolithography system 900 including a light source 910, an illumination mirror system 920, the reticle stage 940, a blinder 960, a projection mirror system 970, and a wafer stage 980. The pellicle 952 may include the pellicle 200a, 200b, 200c, 200d, or 200e as described with reference to FIGS. 1 to 11, or a variant thereof.

The light source 910 may generate EUVL. For example, the light source 910 may generate light with a wavelength of about 13.5 nm, for example, the EUVL, by using carbon plasma. The light source 910 may include a light collector 915. The light collector 915 may collect the EUVL generated from the light source 910 and adjust the EUVL to travel straight in any one direction. For example, the EUVL generated from the light source 910 may pass through the light collector 915 and be irradiated to the illumination mirror system 920.

The illumination mirror system 920 may include a plurality of illumination mirrors 921 to 924. For example, the illumination mirrors 921 to 924 may condense the EUVL to reduce loss of the EUVL to the outside a mirrored irradiation path. In addition, the illumination mirrors 921 to 924 may, for example, uniformly adjust the overall intensity distribution of the EUVL. Accordingly, each of the plurality of illumination mirrors 921 to 924 may include a concave mirror and/or a convex mirror to diversify the path of the EUVL. In addition, the illumination mirror system 920 may shape the EUVL into a square shape, a circular shape, or a bar shape and transmit the EUVL to the reticle stage 940.

The reticle stage 940 may mount the reticle 950 on its lower surface and move in a horizontal direction. For example, the reticle stage 940 may move in a direction indicated by an arrow in the drawing. The reticle stage 940 may include an electrostatic chuck (ESC). The reticle 950 may include optical patterns on one side surface. The reticle 950 may be mounted on a lower surface of the reticle stage 940 such that the side surface on which the optical patterns are formed faces downward in the drawing.

The blinder 960 may be disposed on a lower portion of the reticle stage 940. The blinder 960 may include a slit 962 and a plate 964. The slit 962 may have an aperture shape. The slit 962 may shape the shape of the EUVL transmitted from the illumination mirror system 920 to the reticle 950 on the reticle stage 940. The EUVL transmitted from the illumination mirror system 920 may pass through the slit 962 and be irradiated to the reticle 950 on the reticle stage 940. The EUVL reflected from the reticle 950 on the reticle stage 940 may pass through the slit 962 and be transmitted to the projection mirror system 970. The plate 964 may block the EUVL irradiated to areas other than the slit 962. Accordingly, the blinder 960 may pass part of the EUVL through the slit 962 and block part of the EUVL by using the plate 964. In addition, the EUVL reflected from the reticle 950 mounted on the lower surface of the reticle stage 940 may pass through the slit 962.

The projection mirror system 970 may receive the EUVL reflected from the reticle 950 and passed through the slit 962 and transmit the EUVL to a wafer 990. The projection mirror system 970 may also include a plurality of projection mirrors 971 to 976. The EUVL irradiated onto the wafer 990 by the projection mirrors 971 to 976 may include virtual aerial image information of the optical patterns of the reticle 950. The shape of the EUVL irradiated onto the wafer 990 may have the shape formed by the slit 962. The plurality of projection mirrors 971 to 976 may correct various aberrations.

The wafer stage 980 may seat the wafer 990 thereon and move in the horizontal direction. For example, the wafer stage 980 may move in a direction indicated by an arrow in the drawing. The wafer stage 980 may move simultaneously in the same direction as the reticle stage 940 at a constant ratio. For example, when a movement ratio is 10:1 (10%), and when the reticle stage 940 moves 10 μm to the left or right, the wafer stage 980 may move 1 μm in the same direction. Alternatively, when the movement ratio is 5:1 (20%), and when the reticle stage 940 moves 10 μm to the left or right, the wafer stage 980 may move 2 μm in the same direction. The movement ratio may be set in various ways. For example, the wafer stage 980 may move in a step-and-scan manner. The focus of the EUVL irradiated from the projection mirror system 970 may be located on the surface of the wafer 990. For example, a photoresist layer with a certain thickness may be formed on the wafer 990, and the focus of the EUVL may be located within the photoresist layer. The wafer 990 may include semiconductor chips manufactured using the pellicle 952.

In the drawings, paths along which the EUVL travels are conceptually shown to make it easier to understand the inventive concept.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the inventive concept has been particularly shown and described with reference to embodiments thereof, it will be understood that various changes in form and details may be made therein without departing from the spirit and scope of the following claims.

What is claimed is:

1. A photomask assembly comprising:
a mask pattern providing an upper surface and comprising a plurality of pins extending in a vertical direction with respect to the upper surface;
a pellicle membrane spaced apart from the mask pattern in the vertical direction; and
a frame assembly configured to support the pellicle membrane,
wherein the frame assembly comprises:
a frame body having a plurality of pin holes configured to respectively surround the plurality of pins;
a first magnetic member configured to surround the plurality of pin holes inside the frame body and generate an attractive force on the plurality of pins; and
a second magnetic member disposed in a lower portion of the frame body and configured to generate an attractive force on the upper surface of the mask pattern.

2. The photomask assembly of claim 1, wherein:
the plurality of pins and the plurality of pin holes each have a cylindrical shape, and
the first magnetic member has a ring shape and faces inner side surfaces of the plurality of pin holes.

3. The photomask assembly of claim 1, wherein:
the plurality of pins and the plurality of pin holes each have a square pillar shape, and
the first magnetic member is one of a plurality of first magnetic members, which respectively face inner side surfaces of the plurality of pin holes.

4. The photomask assembly of claim 3, wherein:
the frame body has a first width in a first horizontal direction orthogonal to the vertical direction and a second width in a second horizontal direction orthogonal to the first horizontal direction,
the plurality of pin holes include a first pin hole extending in the first horizontal direction and a second pin hole extending in the second horizontal direction,
a length of the first pin hole in the first horizontal direction is longer than half the first width, and
a length of the second pin hole in the second horizontal direction is longer than half the second width.

5. The photomask assembly of claim 1, wherein:
the frame body has a square ring shape along a horizontal direction orthogonal to the vertical direction, and
vent holes are formed in lower ends of four corners of the frame body.

6. The photomask assembly of claim 5, wherein the vent holes do not overlap the plurality of pin holes along the vertical direction.

7. The photomask assembly of claim 1, wherein a size of each of the plurality of pin holes is equal to a size of each of the plurality of pins.

8. The photomask assembly of claim 1, wherein the first magnetic member is spaced apart from the second magnetic member in a first horizontal direction orthogonal to the vertical direction.

9. The photomask assembly of claim 1, wherein a length of the first magnetic member in the vertical direction is longer than a length of the second magnetic member in the vertical direction.

10. The photomask assembly of claim 1, wherein the mask pattern includes tantalum (Ta).

11. The photomask assembly of claim 1, wherein the second magnetic member is exposed on a lower surface of the frame body.

12. A photomask assembly comprising:
a mask pattern providing an upper surface and comprising a plurality of pins extending in a vertical direction with respect to the upper surface;
a pellicle membrane spaced apart from the mask pattern in the vertical direction;
a frame assembly configured to support the pellicle membrane; and
an adhesive layer disposed between the pellicle membrane and the frame assembly and configured to attach the pellicle membrane to the frame assembly,
wherein the frame assembly comprises:
a frame body comprising a plurality of pin holes configured to respectively surround the plurality of pins;
a first magnetic member configured to surround the plurality of pin holes inside the frame body and generate an attractive force on the plurality of pins;
a plurality of second magnetic members disposed to be spaced apart from each other in a lower portion of the frame body and each configured to generate an attractive force on the upper surface of the mask pattern; and
a plurality of third magnetic members each disposed between a pair of second magnetic members among the plurality of second magnetic members spaced apart from each other in the lower portion of the frame body and each configured to generate an attractive force on the upper surface of the mask pattern.

13. The photomask assembly of claim 12, wherein a magnetic permeability of each of the plurality of second magnetic members is greater than a magnetic permeability of each of the plurality of third magnetic members.

14. The photomask assembly of claim 12, wherein a magnetic material included in each of the plurality of second magnetic members is different from a magnetic material included in each of the plurality of third magnetic members.

15. The photomask assembly of claim 12, wherein each of the plurality of second magnetic members and each of the plurality of third magnetic members are spaced apart from each other in a horizontal direction orthogonal to the vertical direction.

16. The photomask assembly of claim 12, wherein the plurality of second magnetic members and the plurality of third magnetic members are exposed on a lower surface of the frame body.

17. The photomask assembly of claim 12, wherein:
the plurality of pins and the plurality of pin holes each have a cylindrical shape, and
the first magnetic member has a ring shape and is exposed on inner side surfaces of each of the plurality of pin holes.

18. The photomask assembly of claim 12, wherein a thickness of the frame body in a horizontal direction is equal to a thickness of each of the plurality of second magnetic members in the horizontal direction and a thickness of each of the plurality of third magnetic members in the horizontal direction.

19. A semiconductor chip manufactured using a photomask assembly, wherein the photomask assembly comprises:
a mask pattern providing an upper surface and comprising a plurality of pins each having a cylindrical shape extending in a vertical direction with respect to the upper surface; and
a pellicle coupled to the mask pattern, wherein the pellicle comprises:
a pellicle membrane disposed to be spaced apart from the mask pattern in the vertical direction;
a frame assembly having a square ring shape configured to support the pellicle membrane; and
an adhesive layer disposed between the pellicle membrane and the frame assembly and configured to attach the pellicle membrane to the frame assembly, and
wherein the frame assembly comprises:
a frame body having four cylindrical pin holes configured to respectively fasten the plurality of pins;
a first magnetic member configured to surround the four cylindrical pin holes inside the frame body and generate an attractive force on the plurality of pins; and
a plurality of second magnetic members spaced apart from each other in a lower portion of the frame body and each configured to generate an attractive force on the upper surface of the mask pattern.

20. The semiconductor chip of claim 19, wherein:
the frame assembly having the square ring shape has vent holes in lower ends of four edge portions, and
the vent holes each have an ‘L’ shape.
